(19) United States
(12) Patent Application Publication
(10) Pub. No.: US 2026/0128259 A1
(43) Pub. Date: May 7, 2026

(54) Plasma Processing Apparatus and Plasma Processing Method

(71) Applicant: Tokyo Electron Limited, Tokyo (JP)

(72) Inventors: Koji KOTANI, Osaka (JP); Ikki KON, Kanagawa (JP)

(21) Appl. No.: 19/371,814

(22) Filed: Oct. 28, 2025

(30) Foreign Application Priority Data
Nov. 1, 2024 (JP) 2024-192682

(51) Int. Cl. H01J 37/32

(52) U.S. Cl. CPC H01J 37/3244; H01J 37/32816; H01J 2237/335

(57) ABSTRACT

Provided is a plasma processing apparatus for removing a film formed on a peripheral edge of a substrate using plasma, comprising: a processing chamber configured to be depressurized and accommodating the substrate; a substrate support located in the processing chamber and configured to support the substrate; an injection head located above the substrate support and configured to inject a gas toward the substrate supported by the substrate support; a plasma supply mechanism configured to supply plasma to the peripheral edge of the substrate supported by the substrate support; and one or more partition plates that divide a space between the substrate supported by the substrate support and the injection head into a plurality of regions along a circumferential direction of the substrate, wherein the injection head injects the gas with an adjusted flow rate for each of the regions.

### CROSS-REFERENCE TO RELATED APPLICATIONS

This application claims priority to Japanese Patent Application No. 2024-192682 filed on November 1, 2024, the entire contents of which are incorporated herein by reference.

### TECHNICAL FIELD

The present disclosure relates to a plasma processing apparatus and a plasma processing method.

### BACKGROUND

Japanese Laid-open Patent Publication No. 2024-70682 discloses a plasma processing apparatus that uses plasma to remove a film formed on a peripheral edge of a substrate. The plasma processing apparatus includes a processing chamber that can be depressurized and accommodates a substrate, a substrate support installed in the processing chamber and having an upper surface serving as a placing surface on which the substrate is placed, an injection head installed above the substrate support to inject a gas toward the placing surface, and a plasma supply mechanism that supplies plasma to the edge of the substrate placed on the placing surface. The plasma processing apparatus further includes an adjustment mechanism for adjusting the relative position and inclination between the injection head and the substrate support.

### SUMMARY

The technique of the present disclosure suppresses non-uniform removal of a film formed on a peripheral edge of a substrate by plasma in a circumferential direction of the substrate using a simple configuration.

In accordance with an aspect of the present disclosure, there is provided a plasma processing apparatus for removing a film formed on a peripheral edge of a substrate using plasma, comprising: a processing chamber configured to be depressurized and accommodating the substrate; a substrate support located in the processing chamber and configured to support the substrate; an injection head located above the substrate support and configured to inject a gas toward the substrate supported by the substrate support; a plasma supply mechanism configured to supply plasma to the peripheral edge of the substrate supported by the substrate support; and one or more partition plates that divide a space between the substrate supported by the substrate support and the injection head into a plurality of regions along a circumferential direction of the substrate, wherein the injection head injects the gas with an adjusted flow rate for each of the regions.

### BRIEF DESCRIPTION OF THE DRAWINGS

FIG. 1 is a longitudinal cross-sectional view schematically showing a configuration of a plasma processing apparatus according to an embodiment.

FIG. 2 is a bottom view of a shower structure.

FIG. 3 is a partially enlarged cross-sectional view of the shower structure.

FIG. 4 is a longitudinal cross-sectional view illustrating another example of a partition plate.

FIG. 5 is a longitudinal cross-sectional view illustrating another example of the partition plate.

FIG. 6 illustrates the effects of providing a gap between an outer peripheral edge of the partition plate and an inner peripheral edge of a peripheral wall.

FIG. 7 illustrates another example of injection holes.

### DETAILED DESCRIPTION

Hereinafter, a plasma processing apparatus according to an embodiment will be described with reference to the accompanying drawings.

In this specification and drawings, like reference numerals will be used for like parts having substantially the same functional configurations, and redundant description thereof will be omitted.

### Plasma processing apparatus

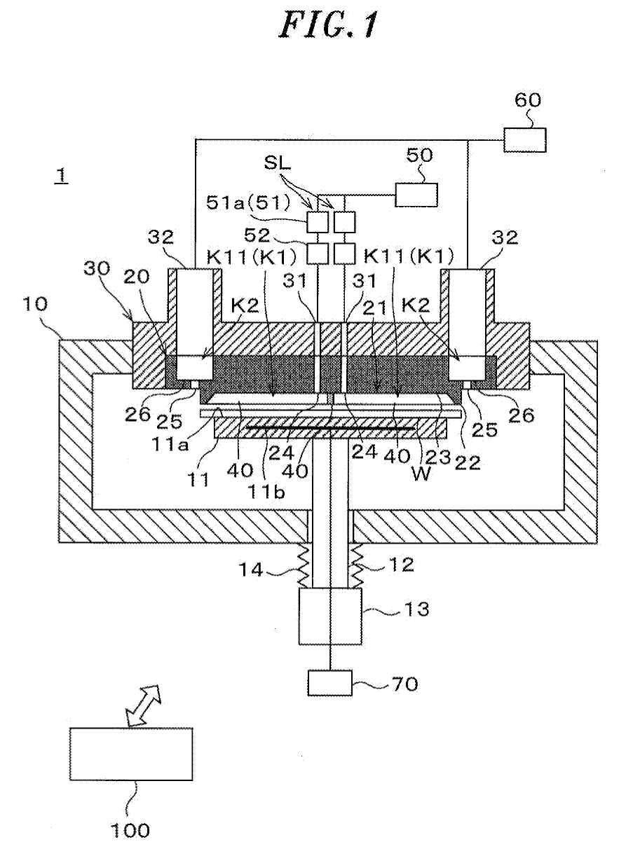

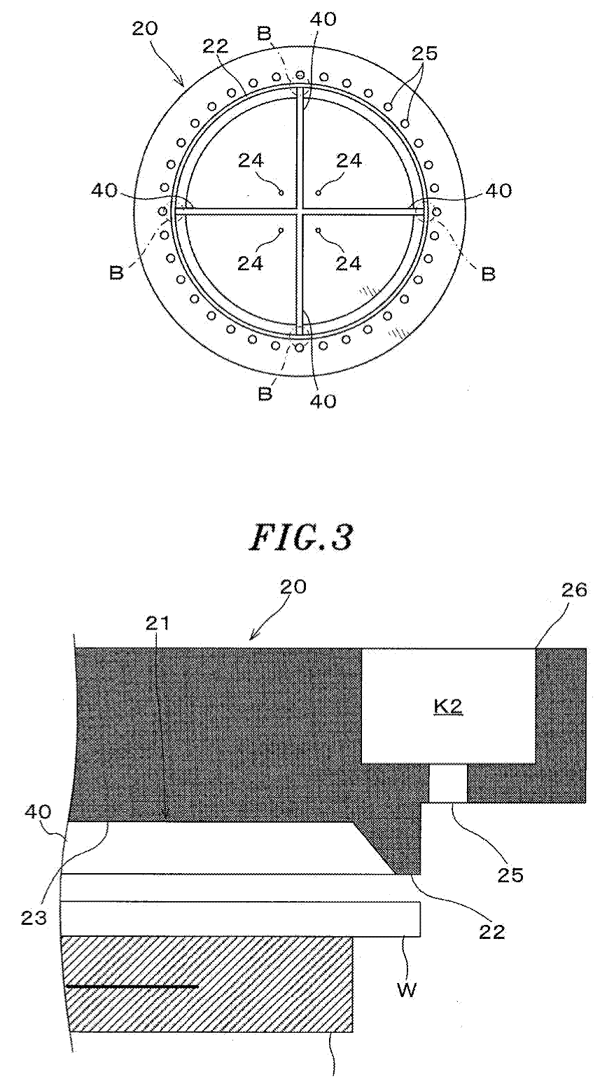

FIG. 1 is a longitudinal cross-sectional view schematically showing a configuration of a plasma processing apparatus according to an embodiment. FIGS. 2 and 3 are a bottom view and a partially enlarged cross-sectional view of a shower structure (to be described later), respectively, and show a state in which a partition plate to be described later is attached.

A plasma processing apparatus 1 shown in FIG. 1 processes a peripheral edge of a semiconductor wafer (hereinafter, referred to as "wafer") W as a substrate using plasma. Specifically, the plasma processing apparatus 1 removes an undesired film formed on the peripheral edge of the wafer W using plasma. The plasma processing apparatus 1 includes a processing chamber 10.

The processing chamber 10 accommodates the wafer W and is configured to be depressurized. Therefore, the processing chamber 10 is connected to an exhaust mechanism (not shown) that exhausts the inside of the processing chamber 10. The exhaust mechanism is connected to the bottom wall of the processing chamber 10, for example. The processing chamber 10 is made of, e.g., aluminum, and is formed in a cylindrical shape. The processing chamber 10 is grounded. A loading/unloading port (not shown) for the wafer W is provided on the sidewall of the processing chamber 10, and a gate valve (not shown) that opens and closes the loading/unloading port is installed at the loading/unloading port.

A stage 11 serving as a substrate support is provided in the processing chamber 10. The stage 11 supports the wafer W. An upper surface 11a of the stage 11 serves as a placing surface on which the wafer W is placed. The upper surface 11a (hereinafter, referred to as "placing surface 11a") is smaller than the wafer W and supports the central portion of the backside of the wafer W. Therefore, when the wafer W is supported on the stage 11, the peripheral edge of the wafer W protrudes beyond the stage 11. In this specification, the term "peripheral edge of the wafer W" refers to a portion of the wafer W that includes at least the bevel portion and the edge tip (APEX) of the wafer W.

The stage 11 is formed in a circular shape having a diameter smaller than that of the wafer W, for example.

Further, an electrode 11b is installed in the stage 11. The electrode 11b is connected to a DC power supply 70. By applying a DC voltage from the DC power supply 70 to the electrode 11b, the Coulomb force is generated, for example. Due to the Coulomb force, the wafer W can be electrostatically attracted on the stage 11.

An upper end of a support member 12 is connected to the center of the bottom surface of the stage 11. The support member 12 extends vertically to penetrate through the bottom wall of the processing chamber 10. The lower end of the support member 12 is connected to a lifting mechanism 13. The lifting mechanism 13 has, e.g., a motor (not shown) as a driving source that generates a driving force for raising and lowering the support member 12. As the support member 12 is raised and lowered by the lifting mechanism 13, the stage 11 and the wafer W supported by the stage 11 are raised and lowered. As a result, the wafer W can be transferred between the stage 11 and a transfer mechanism located outside the apparatus, or the wafer W supported by the stage 11 can become close to a peripheral wall 22 of a shower structure 20 to be described later.

A bellows 14 is provided to surround the outer periphery of the support member 12 between the lifting mechanism 13 and the portion of the bottom wall of the processing chamber 10 through which the support member 12 penetrates, thereby maintaining the airtightness of the processing chamber 10.

The lifting mechanism 13 is controlled by a controller 100 to be described later.

The plasma processing apparatus 1 further includes the shower structure 20. The shower structure 20 functions as an injection head, and is provided with injection holes constituting a plasma supply mechanism. The injection head is provided above the stage 11 and injects a gas toward the wafer W supported on the stage 11. The plasma supply mechanism supplies plasma to the edge of the wafer W supported on the stage 11.

In one embodiment, the shower structure 20 constitutes the top wall, i.e., the ceiling wall of the processing chamber 10 that covers the wafer W supported on the stage 11, together with a support wall 30 that supports the shower structure 20. Further, the shower structure 20 may be formed by separately providing the injection head and the plasma supply mechanism and them combining them.

A space K1 is formed between the shower structure 20 and the wafer W supported on the stage 11. Specifically, the space K1 is formed between the wafer W supported on the stage 11 and a recess 21 formed to be recessed upward in the shower structure 20.

The peripheral wall 22 that forms the recess 21 is formed to extend downward toward the outer periphery of the wafer W supported on the stage 11. Accordingly, the peripheral wall 22 of the shower head 20 becomes close to the wafer W supported on the stage 11. The peripheral wall 22 is formed in an annular shape in plan view (specifically, a circular shape concentric with the wafer W in plan view) as shown in FIG. 2.

Further, in the present disclosure, the "periphery" of the wafer W refers to the peripheral edge of the wafer W and a portion slightly inward from the peripheral edge (e.g., a portion within 10 mm from the peripheral edge of the wafer W). Therefore, at a position facing the peripheral edge of the wafer W supported on the stage 11, the peripheral wall 22 may straddle the peripheral edge of the wafer W and a portion slightly inward from the peripheral edge in plan view, or may overlap only the peripheral edge of the wafer W in plan view.

Further, in plan view, the entire peripheral wall 22 does not need to overlap the outer periphery of the wafer W supported by the stage 11, and only a part of the peripheral wall 22 may overlap the outer periphery of the wafer W in plan view. Therefore, the outermost periphery of the peripheral wall 22 may be located outside the peripheral end of the wafer W supported by the stage 11, and the innermost periphery of the peripheral wall 22 may be located inside the outer periphery of the wafer.

In one example, the outer peripheral surface of the peripheral wall 22 extends vertically, and coincides with the peripheral end of the wafer W supported on the stage 11 in plan view.

Further, in one example, the inner peripheral surface of the peripheral wall 22 is an inclined surface that becomes lower toward the outer side in longitudinal cross-sectional view. In other words, in one example, the recess 21 formed by the peripheral wall 22 is formed in a truncated cone shape. In that case, the upper end of the inner peripheral surface of the peripheral wall 22 is located inside the outer periphery of the wafer W supported on the stage 11, and the lower end thereof is located above the outer periphery of the wafer W, for example.

Further, as shown in FIG. 1, the plasma processing apparatus 1 is provided with partition plates 40 that divide the space K1 defined by the recess 21 having the peripheral wall 22 into a plurality of regions K11 along the circumferential direction of the stage 11. In other words, in the plasma processing apparatus 1, the space K1 is divided by the partition plates 40 into the plurality of regions K11 along the circumferential direction of the wafer W supported on the stage 11. The number of spaces K1 defined by the partition plates 40, i.e., the number of regions K11, is three or more, e.g., four.

Further, in the shower structure 20, an injection hole 24 is installed for each region K11 on a concave surface 23 constituting the recess 21. An inert gas such as argon gas or nitrogen gas is injected from the injection holes 24. The inert gas is injected downward from the injection holes 24. Specifically, the injection direction is a vertically downward direction. In other words, the injection holes 24 are provided to penetrate through the shower structure 20 vertically.

One injection hole 24, for example, is formed in each region K11.

The injection hole 24 for each region K11 is connected to an inert gas supply source 50 through a supply line SL including a gas channel 31 (to be described later) in the support wall 30. The supply line SL is provided with a supply control device group 51 including a flow rate control valve 51a serving as a flow rate controller for controlling the flow rate of the inert gas and an on-off valve (not shown) for switching on/off of the supply of the inert gas.

With this configuration, the shower structure 20 can inject an inert gas with an adjusted flow rate for each region K11.

Further, the supply control device group 51 is controlled by the controller 100 to be described later.

Further, a pressure sensor 52 is provided at the supply line SL to measure the pressure in the supply line SL, which substantially matches the pressure in the corresponding region K11. Specifically, the pressure sensor 52 is provided at the downstream side of the flow rate control valve 51a on the supply line SL, and more specifically, at the downstream side of the supply control device group 51.

Further, the pressure sensor 52 may be attached to a portion of the shower structure 20 that constitutes the injection head so that the actual pressure in the region K11 can be measured.

Further, the shower structure 20 has injection holes 25 on the outer side of the peripheral wall 22. The injection holes 25 injects plasma that is an etchant. The plasma injected from the injection holes 25 is supplied to the portion of the shower structure 20 that is adjacent to the wafer W supported on the stage 11, i.e., to the outer periphery of the peripheral wall 22.

As shown in FIG. 2, a plurality of injection holes 25 are arranged in an annular shape along the outer periphery of the peripheral wall 22 in plan view. As shown in FIG. 1, each of the injection holes 25 is connected to a remote plasma source 60 installed outside the processing chamber 10 through a gas channel 32 (to be described later) in the support wall 30. Specifically, each of the injection holes 25 is connected to the remote plasma source 60 via a diffusion space K2 and the gas channel 32 in the support wall 30. The diffusion space K2 is a channel connected to the injection holes 25 from the top. The plasma from the gas channel 32 in the support wall 30 is diffused in the diffusion space K2 and supplied to each of the injection holes 25. The diffusion space K2 is formed in a circular shape concentric with the wafer W supported on the stage 11.

Further, the remote plasma source 60 supplies reactive plasma, specifically, radicals such as oxygen radicals. For example, the remote plasma source 60 can activate an inert gas, such as argon gas, and an oxygen-containing gas, such as oxygen gas, supplied to the remote plasma source 60 with plasma, thereby forming oxygen radicals.

The injection direction of plasma from the injection holes 25 is common to all the injection holes 25, for example, and is a vertically downward direction.

Further, the injection holes 25 are located so as not to overlap the wafer W supported on the stage 11 in plan view. In other words, the injection holes 25 are located outside the peripheral edge of the wafer W in plan view. The distance from each injection hole 25 to the peripheral edge of the wafer W is set such that the peripheral edge of the wafer W can be efficiently processed by the plasma from the injection holes 25.

The shower structure 20 further includes a recess 26 that is recessed downward and has an upper opening.

The recess 26 is formed in an annular shape in plan view (specifically, a circular ring shape in plan view). The annular diffusion space K2 is formed by blocking the upper opening of the recess 26 with the support wall 30.

The gas channels 31 and 32 are provided in the support wall 30.

The gas channel 31 is provided for each region K11. For example, the gas channel 31 is connected to the injection holes 24 of the corresponding region K11 and extends upward (specifically, vertically upward).

A plurality of gas channels 32 are provided along the diffusion space K2 in plan view, for example. Each gas channel 32 is connected to the diffusion space K2 and extends upward (specifically, vertically upward).

The above-described partition plates 40 are formed in a plate shape. Further, as shown in FIGS. 2 and 3, the partition plates 40 are provided to pass through the deepest part of the recess 21 of the shower structure 20. In other words, the partition plates 40 are formed to protrude from the concave surface 23 constituting the recess 21 toward the stage 11.

For example, the outer peripheral edges of the partition plates 40 are connected to the inner peripheral edge of the peripheral wall 22.

Further, the height of the lower end of each partition plate 40 relative to the wafer W supported on the stage 11 is the same as the height of the lower end of the peripheral wall 22.

The width of the partition plate 40 in plan view, i.e., the thickness of the partition plate 40, is, e.g., 1 mm to 5 mm.

The partition plates 40 are attached to the shower structure 20, for example. The partition plates 40 may be included in the shower structure 20. Specifically, the partition plates 40 may be formed integrally with the shower structure 20.

Each of the shower structure 20, the support wall 30, and the partition plates 40 is made of, e.g., aluminum.

The plasma processing apparatus 1 configured as described above is provided with at least one controller 100. The controller 100 processes computer-executable instructions that cause the plasma processing apparatus 1 to perform various processes described in the present disclosure. The controller 100 may be configured to control individual elements of the plasma processing apparatus 1 to perform the various processes described herein. In one embodiment, the controller 100 may be partially or entirely included in the plasma processing apparatus 1. The controller 100 may include a processing part, a storage part, and a communication interface. The controller 100 may be implemented by a computer, for example. The processing part may be configured to read out a program that provides logic or routines capable of executing various control operations from the storage part, and to execute the read program to perform various control operations. The program may be stored in advance in the storage part or may be acquired via a medium when needed. The acquired program is stored in the storage part, and read and executed from the storage part by the processing part. The medium may be a computer-readable storage medium or a communication line connected to the communication interface. The storage medium may be temporary or non-temporary. The processing part may be a central processing unit (CPU) or one or more circuits. The memory part may include a random access memory (RAM), a read only memory (ROM), a hard disk drive (HDD), a solid state drive (SSD), or a combination thereof. The communication interface may communicate with the plasma processing apparatus 1 through a communication line such as a local area network (LAN).

Example of processing performed by plasma processing apparatus 1

Hereinafter, an example of processing performed by the plasma processing apparatus 1 will be described. It is assumed that the wafer W to be processed in the following process has been subjected to film formation.

### Step S1: loading of wafer W

For example, first, the wafer W is loaded into the processing chamber 10.

Specifically, the wafer W supported by a transfer arm of a transfer mechanism installed outside the plasma processing apparatus 1 is loaded into the processing chamber 10. Then, the transfer arm is lowered, and the wafer W is transferred from the transfer arm to the stage 11. Thereafter, the transfer arm is retracted from the processing chamber 10, and the inside of the processing chamber 10 is depressurized to a predetermined vacuum level by an exhaust mechanism (not shown).

### Step S2: bringing wafer W close to shower structure 20

Next, the wafer becomes close to the shower structure 20 serving as the injection head as described above.

Specifically, the stage 11 supporting the wafer W is raised. Accordingly, the height of the wafer W supported on the stage 11 reaches a processing height, and the distance from the outer periphery of the wafer W to the peripheral wall 22 of the shower structure 20 becomes a predetermined distance.

### Step S3: cleaning plasma processing

Next, a film formed on the peripheral edge of the wafer W is removed using plasma.

This processing includes a plasma supply step (step S3a) and an inert gas injection step (step S3b).

### Step S3a

In the plasma supply step, the plasma is supplied to the space around the outer periphery of the portion (specifically, the peripheral wall 22) constituting the injection head of the shower structure 20.

Specifically, radicals such as oxygen radicals from the remote plasma source 60 are supplied into the processing chamber 10 through the injection holes 25 of the shower structure 20. Due to the radicals, films formed on the front and rear surfaces of the peripheral edge of the wafer W are removed. In other words, the peripheral edge of the wafer W is cleaned.

### Step S3b

In the inert gas injection step, a gas having a flow rate adjusted for each region K11 is injected from the shower structure 20 into each of the plurality of regions K11 formed by the partition plates 40.

Specifically, an inert gas such as argon gas from the supply source 50 is injected toward the wafer W supported on the stage 11 through the injection holes 24 of the shower structure 20 provided for each region K11. Accordingly, the inert gas is diffused between the recess 21 of the shower structure 20 and the wafer W, and then flows toward the outer peripheral edge of the wafer W. Then, the flow of the inert gas toward the outer side (of the wafer W) is formed in the gap (hereinafter, may be referred to as "outer peripheral gap") between the peripheral wall 22 of the shower structure 20 and the outer periphery of the wafer W supported on the stage 11 (specifically, between the bottom surface of the peripheral wall 22 and the outer peripheral surface of the wafer W).

By executing step S3b during step S3a, the radicals from the injection holes 25 are prevented from traveling toward the center of the wafer W through the outer peripheral gap, and the film at the center of the wafer W is prevented from being removed by the radicals. Further, by starting step S3b prior to step S3a, it is possible to further suppress the radicals from reaching the center of the wafer W.

Further, in step S3b, the inert gas is injected such that the pressures in the regions K11 becomes uniform. In other words, the flow rate of the inert gas supplied to the injection hole 24 of each region K11 is determined based on the measurement results of the pressure sensor 52 for the corresponding region K11 such that the pressure in each region K11 becomes a predetermined pressure, for example.

Accordingly, if the outer peripheral gap is not uniform in the circumferential direction of the wafer W supported on the stage 11, for example, it is possible to suppress the flow rate of the inert gas flow, which is directed outward and formed at the outer peripheral gap, from becoming non-uniform in the circumferential direction. Therefore, it is possible to suppress the removal results (specifically, the removal width) of the film at the peripheral edge of the wafer W by the plasma from becoming non-uniform in the circumferential direction due to the non-uniform outer peripheral gap in the circumferential direction. In the following description, "circumferential direction" refers to "circumferential direction of the wafer W supported on the stage 11."

In the case of injecting the inert gas in step S3b, if the outer peripheral gap can be measured at multiple locations spaced apart from one another in the circumferential direction, the flow rate of the inert gas to be supplied to the injection holes 24 of the respective regions K11 may be determined based on the measurement results of the outer peripheral gap. For example, in the region K11 with a large outer peripheral gap, the flow rate of the inert gas to be supplied to the injection hole 24 of the corresponding region K11 may be set to be large.

Further, the non-uniformity of the outer peripheral gap in the circumferential direction may be caused by the deviation of parallelism between the shower structure 20 and the stage 11 (including the differences in flatness of the placing surface 11a of the stage 11 and the bottom surface of the peripheral wall 22 of the shower structure 20), or the warpage of the wafer W.

For example, when a predetermined time has elapsed from the start of the supply of radicals and the injection of the inert gas, the supply and the injection are stopped, and the cleaning of the peripheral portion of the wafer W is completed.

Further, the injection of the inert gas may be performed at least either before or after the supply of radicals.

### Step S4: unloading of wafer W

Then, the wafer W is unloaded from the processing chamber 10.

Specifically, the stage 11 is lowered, the wafer W supported on the stage 11 is separated from the shower structure 20 and unloaded from the processing chamber 10 in the reverse order of step S1.

Accordingly, the series of processes for the first wafer W is completed and, then, the series of processes for the next wafer W is performed.

The injection of the inert gas in step S3b may be performed based on the results of the prior cleaning such that the cleaning of the wafer W becomes uniform in the circumferential direction.

Specifically, if there is a portion A whose the film removal width exceeds a target value in the prior cleaning, the flow rate of the inert gas supplied to the injection holes 24 of the region K11 closest to the portion A is set to be high for the wafer W to be processed. Accordingly, the outward flow of the inert gas with a high flow rate can be formed at the outer peripheral gap around the region K11 closest to the portion A. As a result, the removal width of the film by cleaning of the portion A can become closer to the target value. Hence, it is possible to suppress the removal results (specifically, the removal width) of the film at the peripheral edge of the wafer W by the plasma from becoming non-uniform in the circumferential direction due to the non-uniformity of the outer peripheral gap or the plasma supply amount in the circumferential direction.

Further, the cleaning may be performed in advance on a plurality of wafers W at different flow rates of the inert gas, and the flow rate of the inert gas that produces the best circumferential cleaning results may be used for actual processing. Hence, it is also possible to suppress the removal results (specifically, the removal width) of the film at the peripheral edge of the wafer W by the plasma from becoming non-uniform in the circumferential direction due to the non-uniformity of the outer peripheral gap or the plasma supply volume in the circumferential direction.

The factors that cause the non-uniformity of the outer peripheral gap in the circumferential direction are described above. Further, the factors that cause the non-uniformity of the plasma supply amount in the circumferential direction include the number of injection holes 25, the position of the gas channel 32, and the non-uniformity of exhaust in the circumferential direction.

### Major effects of embodiment

As described above, in the present embodiment, the plasma processing apparatus 1, which processes the peripheral edge of the wafer W with plasma, includes the shower structure 20 that is located above the stage 11 and functions as an injection head for injecting a gas toward the wafer W supported on the stage 11. Further, in the present embodiment, the plasma processing apparatus 1 includes the partition plates 40 that divide the space K1 between the portion of the shower structure 20 functioning as the injection head and the wafer W supported on the stage 11 into the plurality of regions K11 along the circumferential direction. Further, in the plasma processing apparatus 1, the shower structure 20 functioning as the injection head injects a gas with a flow rate adjusted for each region K11. In other words, the plasma processing apparatus 1 is configured to adjust the flow rate of the gas injected from the shower structure 20 for each region K11. Therefore, the flow rate of the inert gas flowing in the gap, i.e., the outer peripheral gap, between the bottom surface of the peripheral wall 22 constituting the injection head of the shower structure 20 and the surface of the outer periphery of the wafer W can be adjusted in the circumferential direction. Hence, it is possible to suppress the removal results (specifically, the removal width) of the film at the peripheral edge of the wafer W by the plasma from becoming non-uniform in the circumferential direction due to the non-uniformity of the outer peripheral gap or the plasma supply amount in the circumferential direction.

Further, the present embodiment does not require a complicated mechanism such as the adjustment mechanism for adjusting the relative position and the inclination of the injection head and the stage, which is included in the apparatus disclosed in Patent Document 1.

Thus, the present embodiment can suppress the removal of the film at the peripheral edge of the wafer W by the plasma from becoming non-uniform in the circumferential direction with a simple configuration.

Further, according to the results of simulation conducted by the inventors of the present disclosure, in the case where the partition plates 40 were not included in the plasma processing apparatus 1, even when the gas was injected from the four injection holes 24 at different flow rates, the flow rate of the inert gas flow, which was formed at the outer peripheral gap, was uniform in the circumferential direction of the wafer W. On the contrary, in the case where the partition plates 40 were included in the plasma processing apparatus 1, when the gas was injected from the four injection holes 24 at different flow rates, the flow rate of the inert gas flow, which was formed at the outer peripheral gap, was also different.

Hence, the partition plates 40 are included in the plasma processing apparatus 1.

### Other examples of partition plate 40

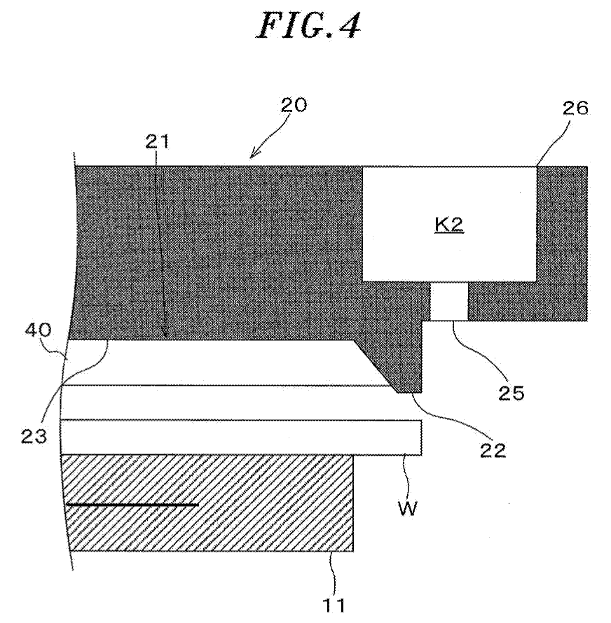

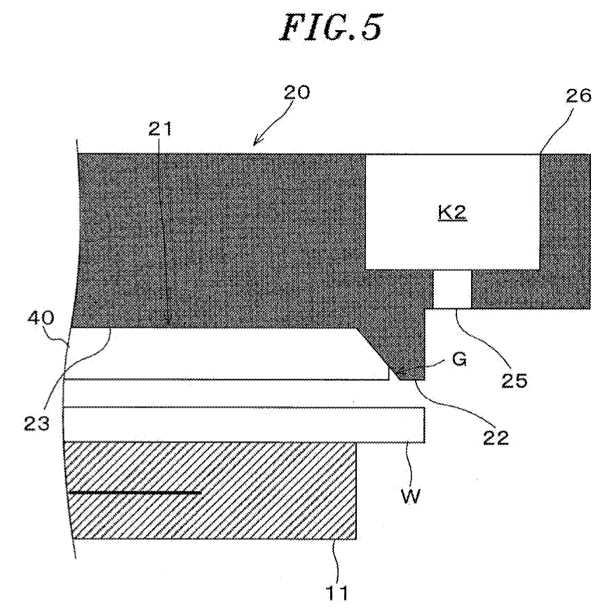

FIGS. 4 and 5 are longitudinal cross-sectional views illustrating other examples of the partition plate 40.

In the above example, the height of the lower end of each partition plate 40 relative to the wafer W supported on the stage 11 was the same as the height of the lower end of the peripheral wall 22. Alternatively, as shown in FIG. 4, the height of the lower end of each partition plate 40 relative to the wafer W supported on the stage 11 may be higher than the height of the lower end of the peripheral wall 22.

In other words, the height of the lower end of the partition plate 40 from the stage 11 may be set to be higher than or equal to the height of the lower end of the peripheral wall 22 from the stage 11. Accordingly, it is possible to suppress large variation of the flow rate of the inert gas at the portions of the partition plates 40 near the outer peripheral gap compared to other portions.

Further, when the height of the lower end of the partition plate 40 relative to the height of the wafer W supported on the stage 11 is equal to and the height of the lower end of the peripheral wall 22, the inert gas supplied to one region K11 is less likely to flow into the adjacent region K11 through the gap between the partition plates 40 and the wafer W compared to when the lower end of the partition plate 40 is higher than the lower end of the peripheral wall 22. Therefore, in the above case, when the flow rates of the inert gas supplied to the injection holes 24, i.e., the injection flow rates of the inert gas from the injection holes 24, are set to be different between the regions K11, the amount of the inert gas flowing along the wafer W toward the outer peripheral gap can be more clearly different between the regions K11. Accordingly, it is possible to increase the degree of change in the flow rate of the inert gas flowing through the outer peripheral gap relative to the flow rate of the inert gas supplied to the injection holes 24.

On the other hand, when the height of lower end of each partition plate 40 relative to the wafer W supported on the stage 11 is higher than the height of the lower end of the peripheral wall 22, the following effect can be achieved. In other words, in the case of intentionally varying the flow rate of the inert gas flowing through the outer peripheral gap via the regions K11 between adjacent regions K11, it is possible to suppress abrupt changes in the flow rate of the inert gas in the circumferential direction at portions B (see FIG. 2) near the outer edges of the partition plates 40.

Further, in the above example, the outer peripheral edge of the partition plate 40 was connected to the inner peripheral edge of the peripheral wall 22. Alternatively, as shown in FIG. 5, a gap G may be provided between the outer peripheral edge of the partition plate 40 and the inner peripheral edge of the peripheral wall 22. Specifically, the height of the lower end of the partition plate 40 from the stage 11 may be equal to the height of the lower end of the peripheral wall 22 from the stage 11, and the gap G may be provided between the outer peripheral edge of the partition plate 40 and the inner peripheral edge of the peripheral wall 22.

Accordingly, it is possible to achieve the same effects as those obtained when the height of the lower end of each partition plate 40 relative to the wafer W supported on the stage 11 is higher than the height of the lower end of the peripheral wall 22, thereby suppressing abrupt changes in the flow rate of the inert gas in the circumferential direction at the portions B (see FIG. 2) near the outer edges of the partition plates 40.

Further, by providing the gap G, the following effects can be achieved. FIG. 6 illustrates the effects of providing the gap, and shows the results of simulation of the flow velocity of the inert gas flowing along the wafer W. In the simulation, the height of the lower end of the partition plate 40 from the stage 11 was set to be equal to the height of the lower end of the peripheral wall 22 from the stage 11, and no gap G was provided between the outer peripheral edge of the partition plate 40 and the inner peripheral edge of the peripheral wall 22. Further, in the simulation, the inert gas was supplied to the four regions K11 at different flow rates. Specifically, the inert gas was supplied to the four regions K11 at 1 slm, 2 slm, 3 slm, and 4 slm. In FIG. 6, the region where the flow velocity is high is illustrated in a darker color, and the region where the flow velocity is low is illustrated in a lighter color.

As shown in FIG. 6, when there was no gap G, the flow of the inert gas, which is formed at the outer peripheral gap, may become weaker at connection portions C between the outer edges of the partition plates 40 and the inner peripheral edge of the lower end of the peripheral wall 22 than at the portions outside the connection portions C. This can be suppressed by providing the gap G. Therefore, a sufficient flow rate of the inert gas can be ensured even near the connection portions C, which makes it possible to suppress the increase in the removal width of the film by plasma near the connection portions C. Further, when the flow of the inert gas, which is formed at the outer peripheral gap, is extremely different due to the different flow rates of the inert gas between adjacent regions K11, such as two upper regions K11 in the upper part of FIG. 6, it is possible to mitigate abrupt changes in the flow of the inert gas in the circumferential direction near the connection portions C of the two regions K11 by providing the gap G.

### Other examples of injection holes 24

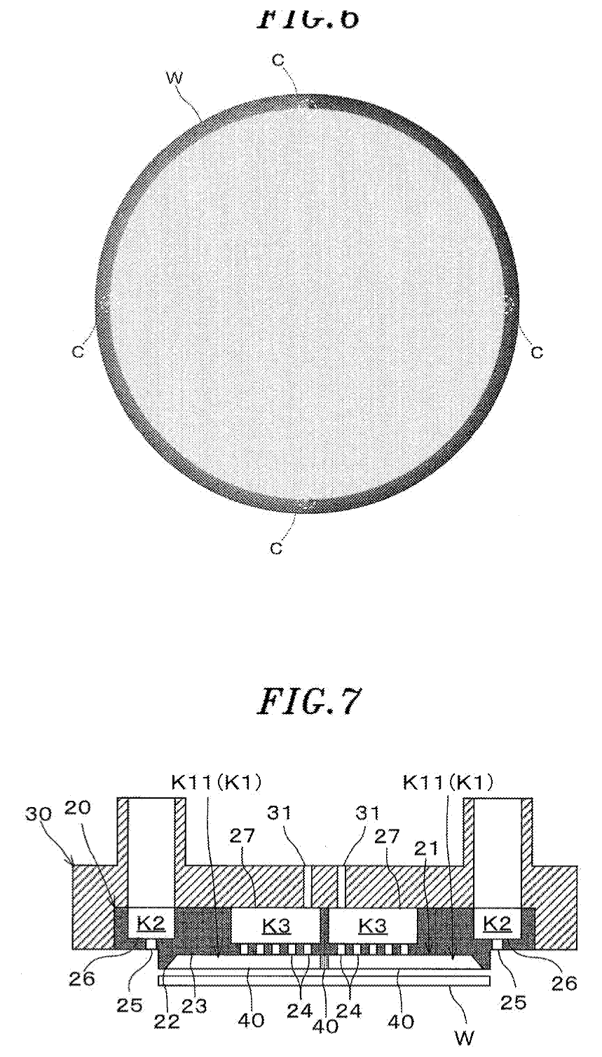

In the above example, one injection hole 24 was provided for each region K11. Alternatively, as shown in FIG. 7, a plurality of injection holes 24 may be provided for each region K11. Specifically, the injection holes 24 may be two-dimensionally arranged on the concave surface 23 for each region K11.

Accordingly, it is possible to suppress the flow of the inert gas toward the outer peripheral gap along the wafer W from becoming non-uniform in the circumferential direction in the same region.

In the present embodiment, the injection hole 24 of each regions K11 is connected to the inert gas supply source 50 through the supply line SL including the gas channel 31 and a diffusion space K3 provided for each region K11, for example. The diffusion space K3 has a shape in which a circular plate concentric with the wafer W supported on the stage 11 is divided along the circumferential direction by the number of regions K11. Further, each diffusion space K3 is formed by blocking a recess 27, which is recessed downward and has an upper opening, provided in the shower structure 20 with the support wall 30.

### Other examples of shape of recess 21

In the above example, the inner circumferential surface of the peripheral wall 22 is formed as an inclined surface that is lowered outward in longitudinal cross section, unlike the outer circumferential surface thereof, and the recess 21 formed by the peripheral wall 22 has a truncated cone shape. Alternatively, the inner circumferential surface of the peripheral wall 22 may extend vertically, similarly to the outer circumferential surface thereof, and the recess 21 formed by the peripheral wall 22 may have a cylindrical shape with a lid and no bottom.

### Modification of substrate support

In the above example, the substrate support was the stage 11 that supports the wafer W on a surface. The substrate support may also include a plurality of pin-shaped members that support the wafer W at points. By using the stage 11, a temperature control mechanism for controlling the temperature of the wafer W can be easily provided in the stage 11. The temperature control mechanism may be, e.g., a resistance heater or a temperature control medium channel.

It should be noted that the above-described embodiments are illustrative in all respects and are not restrictive. The above-described embodiments may be omitted, replaced, or changed in various forms without departing from the scope of the appended claims and the gist thereof. For example, the components of the above-described embodiments can be randomly combined. The effects of the components for arbitrary combination can be obtained from the corresponding arbitrary combination, other effects apparent to those skilled in the art can also be obtained.

Further, the effects described in the present specification are merely explanatory or exemplary, and are not restrictive. In other words, in the technique related to the present disclosure, other effects apparent to those skilled in the art can be obtained from the description of the present specification in addition to the above-described effects or instead of the above-described effects.

Further, the following configuration examples are also included in the technical scope of this disclosure.

(1) A plasma processing apparatus for removing a film formed on a peripheral edge of a substrate using plasma, comprising:

a processing chamber configured to be depressurized and accommodating the substrate;

a substrate support located in the processing chamber and configured to support the substrate;

an injection head located above the substrate support and configured to inject a gas toward the substrate supported by the substrate support;

a plasma supply mechanism configured to supply plasma to the peripheral edge of the substrate supported by the substrate support; and

one or more partition plates that divide a space between the substrate supported by the substrate support and the injection head into a plurality of regions along a circumferential direction of the substrate,

wherein the injection head injects the gas with an adjusted flow rate for each of the regions.

(2) The plasma processing apparatus of (1), wherein the injection head has a recess that is recessed upward to define the space, and

said one or more partition plates pass through the deepest portion of the recess.

(3) The plasma processing apparatus of (2), wherein a height of a lower end of the partition plate measured from the substrate support is greater than or equal to a height of a lower end of a peripheral wall forming the recess of the injection head measured from the substrate support.

(4) The plasma processing apparatus of (2) or (3), wherein a gap is provided between the peripheral wall forming the recess of the injection head and the outer edge of the partition plate.

(5) The plasma processing apparatus of any one of (1) to (4), wherein each of a plurality of gas supply lines is connected to each portion of the injection head corresponding to a respective one of the regions, and

a flow rate controller is provided at each supply line.

(6) The plasma processing apparatus of any one of (1) to (5), wherein a pressure sensor is provided to measure a pressure in each of the regions.

(7) The plasma processing apparatus of any one of (1) to (6), wherein a plurality of gas injection holes are provided for each portion of the injection head corresponding to a respective one of the regions.

(8) A plasma processing method for removing a film formed on a peripheral edge of a substrate using plasma, comprising:

bringing an injection head and the substrate close to each other;

injecting a gas from the injection head into a plurality of regions obtained by dividing a first space between the injection head and the substrate along a circumferential direction of the substrate at a flow rate adjusted for each region; and

supplying plasma into a second space surrounding the outer periphery of the injection head.

(9) The plasma processing method of (8), wherein in said injecting, the gas is injected into the respective regions such that pressures in the respective regions become the same.

1. A plasma processing apparatus for removing a film formed on a peripheral edge of a substrate using plasma, comprising:
a processing chamber configured to be depressurized and accommodating the substrate;
a substrate support located in the processing chamber and configured to support the substrate;
an injection head located above the substrate support and configured to inject a gas toward the substrate supported by the substrate support;
a plasma supply mechanism configured to supply plasma to the peripheral edge of the substrate supported by the substrate support; and
one or more partition plates that divide a space between the substrate supported by the substrate support and the injection head into a plurality of regions along a circumferential direction of the substrate,
wherein the injection head injects the gas with an adjusted flow rate for each of the regions.

2. The plasma processing apparatus of claim 1, wherein the injection head has a recess that is recessed upward to define the space, and
said one or more partition plates pass through the deepest portion of the recess.

3. The plasma processing apparatus of claim 2, wherein a height of a lower end of the partition plate measured from the substrate support is greater than or equal to a height of a lower end of a peripheral wall forming the recess of the injection head measured from the substrate support.

4. The plasma processing apparatus of claim 2, wherein a gap is provided between the peripheral wall forming the recess of the injection head and the outer edge of the partition plate.

5. The plasma processing apparatus of claim 3, wherein a gap is provided between the peripheral wall forming the recess of the injection head and the outer edge of the partition plate.

6. The plasma processing apparatus of claim 1, wherein each of a plurality of gas supply lines is connected to each portion of the injection head corresponding to a respective one of the regions, and
a flow rate controller is provided at each supply line.

7. The plasma processing apparatus of claim 2, wherein each of a plurality of gas supply lines is connected to each portion of the injection head corresponding to a respective one of the regions, and
a flow rate controller is provided at each supply line.

8. The plasma processing apparatus of claim 3, wherein each of a plurality of gas supply lines is connected to each portion of the injection head corresponding to a respective one of the regions, and
a flow rate controller is provided at each supply line.

9. The plasma processing apparatus of claim 1, wherein a pressure sensor is provided to measure a pressure in each of the regions.

10. The plasma processing apparatus of claim 2, wherein a pressure sensor is provided to measure a pressure in each of the regions.

11. The plasma processing apparatus of claim 3, wherein a pressure sensor is provided to measure a pressure in each of the regions.

12. The plasma processing apparatus of claim 1, wherein a plurality of gas injection holes are provided for each portion of the injection head corresponding to a respective one of the regions.

13. The plasma processing apparatus of claim 2, wherein a plurality of gas injection holes are provided for each portion of the injection head corresponding to a respective one of the regions.

14. The plasma processing apparatus of claim 3, wherein a plurality of gas injection holes are provided for each portion of the injection head corresponding to a respective one of the regions.

15. A plasma processing method for removing a film formed on a peripheral edge of a substrate using plasma, comprising:
bringing an injection head and the substrate close to each other;
injecting a gas from the injection head into a plurality of regions obtained by dividing a first space between the injection head and the substrate along a circumferential direction of the substrate at a flow rate adjusted for each region; and
supplying plasma into a second space surrounding the outer periphery of the injection head.

16. The plasma processing method of claim 15, wherein in said injecting, the gas is injected into the respective regions such that pressures in the respective regions become the same.
